(19) United States
(12) Patent Application Publication
(10) Pub. No.: US 2026/0052785 A1
(43) Pub. Date: Feb. 19, 2026

(54) IMAGE SENSOR

(71) Applicant: Samsung Electronics Co., Ltd., Suwon-si (KR)

(72) Inventor: Jameyung KIM, Suwon-si (KR)

(73) Assignee: Samsung Electronics Co., Ltd., Suwon-si (KR)

(21) Appl. No.: 19/229,041

(22) Filed: Jun. 5, 2025

(30) Foreign Application Priority Data
Aug. 14, 2024 (KR) 10-2024-0108793

(51) Int. Cl. H10F 39/00; H10F 39/18

(52) U.S. Cl. CPC H10F 39/80373; H10F 39/182

(57) ABSTRACT

An image sensor may include a deep element isolation pattern in a substrate, defining pixel region groups, each of the pixel region groups including at least one pixel region, a shallow element isolation pattern filling a shallow trench recessed from one surface of the substrate and defining a plurality of active regions in each of the pixel region groups, a source follower gate disposed on a first active region among the plurality of active regions and including a pair of first vertical portions respectively filling a pair of first gate recesses in the first active region and spaced laterally apart from each other, a source follower channel region defined between the pair of first gate recesses, and a first gate insulating film between the source follower gate and the source follower channel region. A width of the source follower channel region may gradually decrease in a depth direction.

### CROSS-REFERENCE TO RELATED APPLICATION(S)

This U.S. non-provisional application claims priority under 35 USC § 119 to Korean Patent Application No. 10-2024-0108793, filed on Aug. 14, 2024 in the Korean Intellectual Property Office, the disclosure of which is herein incorporated by reference in its entirety.

### BACKGROUND

Some example embodiments relate to an image sensor.

An image sensor is or includes a semiconductor element that converts an optical image into an electrical signal. Recently, with the development of the computer and communication industries, the demand for image sensors with improved performance has increased in various fields such as digital cameras, camcorders, personal communication systems (PCSs), gaming devices, security cameras, and medical micro cameras. The Image sensors can be classified into a charge coupled device (CCD) type and a complementary metal oxide semiconductor (CMOS) type. The CMOS type image sensor is provided with a plurality of pixels arranged two-dimensionally. Each of the pixels includes a photosensitive device such as a photodiode (PD). The photodiode serves to convert incident light into an electrical signal.

### SUMMARY

Some example embodiments may provide an image sensor provided with a transistor having an increased channel width.

Alternatively or additionally, some example embodiments may provide an image sensor with decreased noise and/or decreased leakage current.

Alternatively or additionally, some example embodiments may provide an image sensor in which the manufacturing cost may be reduced and/or the manufacturing difficulty may be lowered.

An image sensor according to some example embodiments may include a deep element isolation pattern in a substrate and defining pixel region groups, each of the pixel region groups including at least one pixel region, a shallow element isolation pattern filling a shallow trench recessed from one surface of the substrate to define a plurality of active regions in each of the pixel region groups, a source follower gate on a first active region among the plurality of active regions and including a pair of first vertical portions, the pair of first vertical portions respectively filling a pair of first gate recesses in the first active region and spaced laterally apart from each other, a source follower channel region defined between the pair of first gate recesses, and a first gate insulating film between the source follower gate and the source follower channel region. A width of the source follower channel region may gradually decrease in a depth direction of the first gate recesses.

Alternatively or additionally an image sensor according to some example embodiments may include a deep element isolation pattern in a substrate to define pixel region groups, each of the pixel region groups including at least one pixel region, a shallow element isolation pattern filling a shallow trench recessed from one surface of the substrate and defining a plurality of first active regions in each of the pixel region groups, a source follower gate in each of the plurality of first active region and including a pair of first vertical portions, the pair of first vertical portions respectively filling a pair of first gate recesses in each of the first active regions and spaced laterally apart from each other, and a source follower channel region being defined between the pair of first gate recesses in each of the first active regions, and first gate insulating films between the source follower gate and the source follower channel regions. A width of each of the source follower channel regions may gradually decrease in a depth direction of the first gate recesses.

Alternatively or additionally, an image sensor according to some example embodiments may include a deep element isolation pattern in a substrate and defining pixel region groups, each of the pixel region groups including at least one pixel region, a shallow element isolation pattern filling a shallow trench recessed from one surface of the substrate and defining a plurality of active regions in each of the pixel region groups, a source follower gate on a first active region among the plurality of active regions and including a pair of first vertical portions, the pair of first vertical portions respectively filling a pair of first gate recesses that are provided in the first active region and spaced laterally apart from each other, a source follower channel region defined between the pair of gate recesses, a transfer gate on a second active region among the plurality of active regions and including a pair of second vertical portions, the pair of second vertical portions respectively filling a pair of second gate recesses in the second active region and spaced laterally apart from each other, a transfer channel region being defined between the pair of second gate recesses, a first gate insulating film between the source follower gate and the source follower channel region, and a second gate insulating film provided between the transfer gate and the transfer channel region. The source follower channel region may be spaced apart from the substrate, the transfer channel region may be connected to the substrate, the substrate under the source follower channel region includes a protrusion protruding toward the source follower channel region, and the maximum width of the transfer channel region may be larger than the maximum width of the source follower channel region.

### BRIEF DESCRIPTION OF DRAWINGS

FIG. 1 is a block diagram of an image sensor according to some example embodiments.

FIG. 2 is a circuit diagram of pixels included in a pixel array of an image sensor according to some example embodiments.

FIG. 3 is a circuit diagram of pixels included in a pixel array of an image sensor according to some example embodiments.

FIG. 4 is a plan view of an image sensor according to some example embodiments.

FIG. 5 is an enlarged plan view of one pixel region group of FIG. 4.

FIG. 6 is a cross-sectional view taken along lines I-I′ and II-II′ of FIG. 5.

FIG. 7 shows an image sensor according to some example embodiments, which is a cross-sectional view corresponding to line I-I′ of FIG. 5,

FIG. 8 is a plan view of an image sensor according to some example embodiments.

FIG. 9 is a cross-sectional view taken along line III-III′ of FIG. 8.

FIGS. 10A, 11A, 12A, 13A, and 14A show a manufacturing method of an image sensor according to some example embodiments, which are cross-sectional views corresponding to line I-I′ of FIG. 5.

FIGS. 10B, 11B, 12B, 13B, and 14B show a manufacturing method of an image sensor according to some example embodiments, which are cross-sectional views corresponding to line II-II′ of FIG. 5.

FIG. 15 is a cross-sectional view of an image sensor according to some example embodiments.

FIG. 16 is a cross-sectional view of an image sensor according to some example embodiments.

### DETAILED DESCRIPTION

Hereafter, some example embodiments will be clearly and thoroughly described with reference to the accompanying drawings.

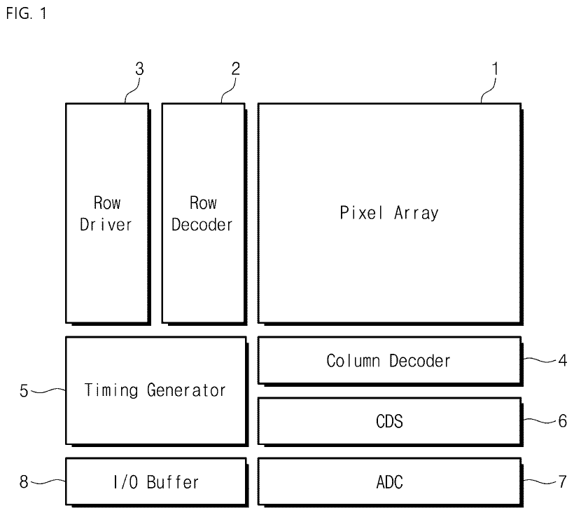

FIG. 1 is a block diagram of an image sensor according to some example embodiments.

Referring to FIG. 1, the image sensor according to some embodiments of the present invention may include a pixel array 1, a row decoder 2, a row driver 3, a column decoder 4, a timing generator 5, a correlated double sampler (CDS) 6, an analog to digital converter (ADC) 7, and an input/output buffer (I/O buffer) 8.

Any of the elements included in FIG. 1 may communicate with any other element included in FIG. 1. For example, any element may send and/or receive signals corresponding to information such as but not limited to data and/or instructions, in a one-to-one and/or one-to-many and/or broadcast manner, over a bus such as a wired and/or wireless bus. The information may be in a digital format and/or an analog format, and may be sent and/or received in a serial and/or parallel manner. Example embodiments are not limited thereto.

The pixel array 1 may include a plurality of pixels arranged two-dimensionally, and the pixels may convert optical signals into electrical signals. The pixel array 1 may be driven by a plurality of driving signals (e.g., a pixel selection signal, a reset signal, and/or a charge transfer signal) transmitted from the row driver 3. The converted electrical signals may be provided to the CDS 6. The pixel array 1 may be arranged as a matrix, e.g., a rectangular or square matrix; example embodiments are not limited thereto.

The row driver 3 may provide the pixel array 1 with the plurality of driving signals for driving the plurality of pixels based on a result of the decoding in the row decoder 2. When the pixels are arranged in a matrix form, the driving signals may be provided in a row unit.

The timing generator 5 may provide a timing signal and a control signal to the row decoder 2 and the column decoder 4.

The CDS 6 may receive the electrical signals generated from the pixel array 1 and may hold and sample the received signals. The CDS 6 may double-sample a specific noise level and a signal level caused by an electrical signal to output a difference level corresponding to the difference between the noise level and the signal level.

The ADC 7 may convert an analog signal corresponding to the difference level output from the CDS 6 into a digital signal and may output the digital signal.

The I/O buffer 8 may latch the digital signals and sequentially output the latched signals to an image signal processor (not shown) based on the result of the decoding in the column decoder 4.

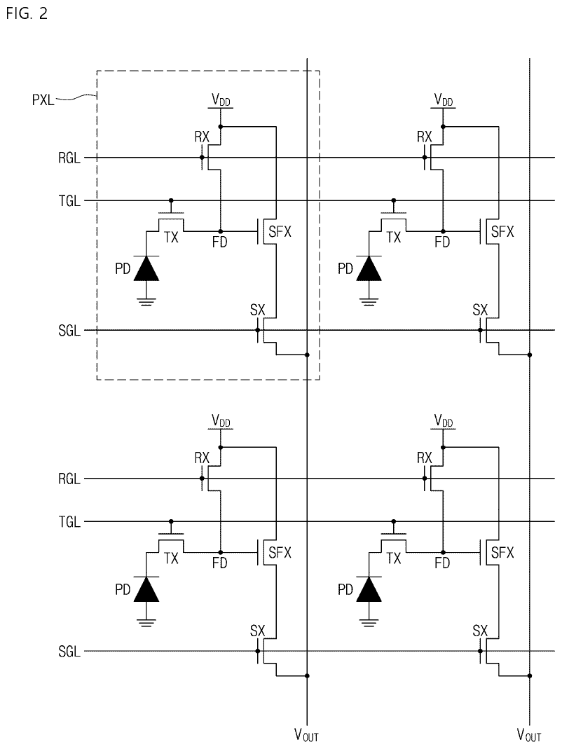

FIG. 2 is a circuit diagram of pixels included in a pixel array of an image sensor according to some example embodiments.

Referring to FIG. 2, the pixel array may include a plurality of pixels PXL, and the pixels PXL may be arranged in a matrix form such as a rectangular or square matrix form. Each of the pixels PXL may include pixel transistors, and the pixel transistors may include a transfer transistor TX and logic transistors RX, SX, and SFX. The logic transistors RX, SX, and SFX may include a reset transistor RX, a selection transistor SX, and a source follower transistor SFX. In addition, each of the pixels PXL may include a photoelectric conversion element PD and a floating diffusion node or floating diffusion region FD.

Each of the logic transistors RX, SX, and SFX and the transfer transistor TX may have the same, or different, physical and/or electrical characteristics. For example, each of the logic transistors RX, SX, and SFX and the transfer transistor TX may have the same, or different, gate widths, gate lengths, and/or dielectric (oxide) thicknesses. Alternatively or additionally, each of the logic transistors RX, SX, and SFX and the transfer transistor TX may have the same, or different, drive currents and/or threshold voltages.

The photoelectric conversion element PD may generate and accumulate photocharges, e.g., electrons and/or holes, in proportion to an amount of light incident from the outside. The photoelectric conversion element PD may include a photodiode, a phototransistor, a photogate, a pinned photodiode, or a combination thereof. The transfer transistor TX may transfer the photocharges generated from the photoelectric conversion element PD to the floating diffusion region FD. A transfer gate of the transfer transistor TX may be connected to a transfer gate line TGL. The floating diffusion region FD may receive and cumulatively store the photocharges generated from the photoelectric conversion element PD.

A gate of the source follower transistor SFX may be connected to the floating diffusion region FD. A drain terminal of the source follower transistor SFX may be connected to a power terminal V_{DD} that may receive a power voltage. The source follower transistor SFX may be controlled according to the amount of photocharges accumulated in the floating diffusion region FD. The source follower transistor SFX may convert a signal corresponding to the amount of input photocharges into a voltage signal.

The reset transistor RX may periodically reset the charges accumulated in the floating diffusion region FD. A gate of the reset transistor RX may be connected to a reset gate line RGL. A source terminal of the reset transistor RX may be connected to the floating diffusion region FD, and a drain terminal of the reset transistor RX may be connected to the power terminal V_{DD}. When the reset transistor RX is turned on, the power voltage of the power terminal V_{DD} may be applied to the floating diffusion region FD through the reset transistor RX. For example, when the reset transistor RX is turned on, the charges accumulated in the floating diffusion region FD may be discharged by the power voltage, thereby resetting the floating diffusion region FD.

The source follower transistor SFX may serve as a source follower buffer amplifier. The source follower transistor SFX may amplify a change in potential in the floating diffusion region FD and output the amplified change in potential to an output line V_{OUT}.

A gate of the selection transistor SX may be connected to a selection gate line SGL. A drain terminal of the selection transistor SX may be connected to the source terminal of the source follower transistor SFX, and a source terminal of the selection transistor SX may be connected to the output line V_{OUT}. The selection transistors SX of the pixels PXL to be readout in row units may be selected by a selection signal applied through a corresponding selection gate line SGL. When the selection transistor SX is turned on, the change in potential amplified by the source follower transistor SFX may be output to the output line V_{OUT} through the selection transistor SX.

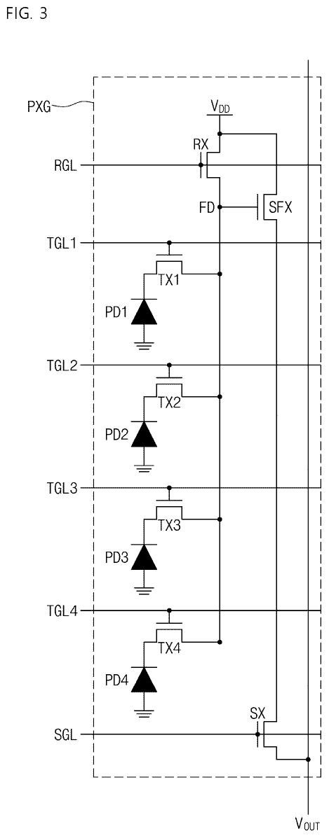

FIG. 3 is a circuit diagram of pixels included in a pixel array of an image sensor according to some example embodiments.

Referring to FIG. 3, the pixel array may include a plurality of pixel groups PXG, and each of the pixel groups PXG may include a plurality of pixels. A circuit diagram of one pixel group PXG is shown in FIG. 3.

Referring to FIG. 3, in some example embodiments, the pixel group PXG may include four pixels (for example, first to fourth pixels). The first to fourth pixels may each include first to fourth transfer transistors TX1, TX2, TX3, and TX4 and first to fourth photoelectric conversion elements PD1, PD2, PD3, and PD4. Gates of the first to fourth transfer transistors TX1, TX2, TX3, and TX4 may be respectively connected to first to fourth transfer gate lines TGL1, TGL2, TGL3, and TGL4. The first to fourth pixels may share the reset transistor RX, the source follower transistor SFX, and the selection transistor SX previously described.

In some example embodiments illustrated in FIG. 3, the pixel group PXG includes four pixels, but some example embodiments are not limited thereto. The number of pixels in the pixel group PXG may be varied. For example, the number of pixels in the pixel group PXG may be eight, more than eight, or less than eight.

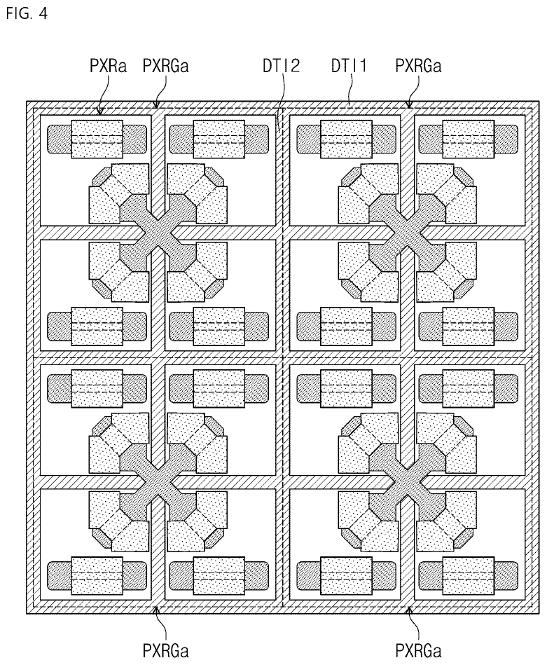

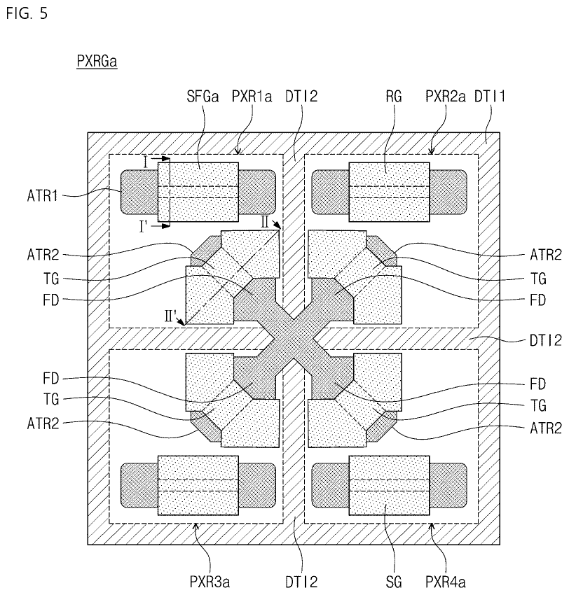

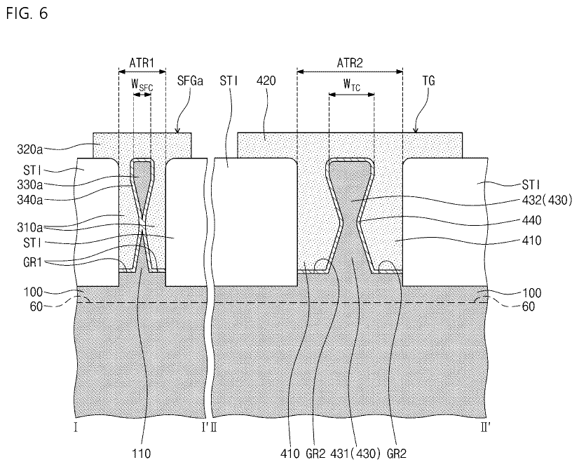

FIG. 4 is a plan view of an image sensor according to some example embodiments. FIG. 5 is an enlarged plan view of one pixel region group of FIG. 4. FIG. 6 is a cross-sectional view taken along lines I-I′ and II-II′ of FIG. 5.

Referring to FIGS. 4, 5, and 6, a first deep element isolation pattern DTI1 may be provided in a substrate 100 to define a plurality of pixel region groups PXRGa, each including a plurality of pixel regions PXRa. A second deep element isolation pattern DTI2 may be provided in the substrate 100 to define the pixel regions PXRa. For example, the second deep element isolation pattern DTI2 may be provided between the pixel regions PXRa.

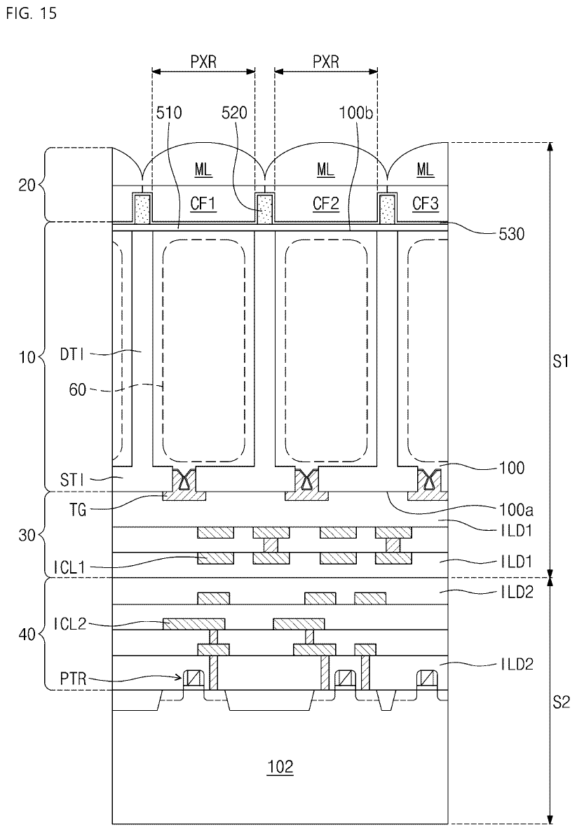

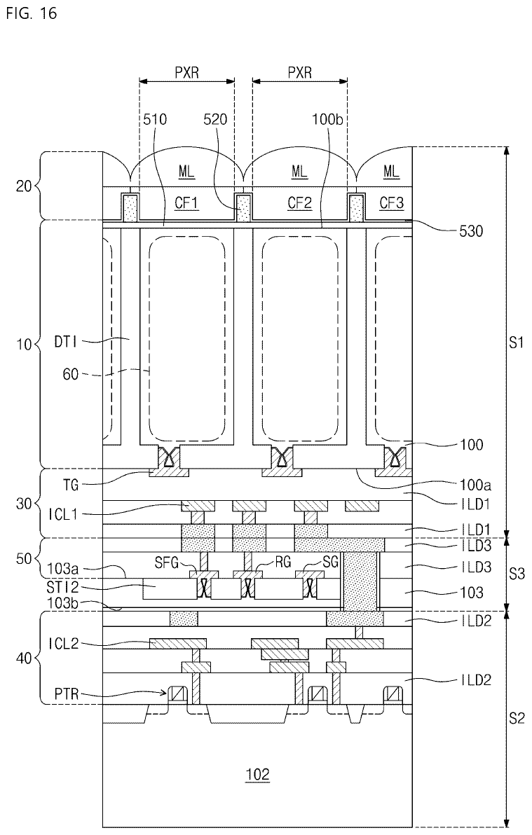

The substrate 100 may have one surface and another surface opposite to the one surface. The one surface of the substrate 100 may be a front surface of the substrate 100, and the other surface of the substrate 100 may be a back surface of the substrate 100. The one surface of the substrate 100 may correspond to a first surface 100a of the first substrate 100 in FIG. 15 or FIG. 16 described below, and the other surface of the substrate 100 may correspond to a second surface 100b of the first substrate 100 in FIG. 15 or FIG. 16. For example, the substrate 100 in FIG. 6 may be a flipped state compared to the first substrate 100 in FIG. 15 or FIG. 16.

In some example embodiments, the first and second deep element isolation patterns DTI1 and DTI2 may pass through the substrate 100. For example, the first and second deep element isolation patterns DTI1 and DTI2 may fill first and second deep trenches passing through the substrate 100. The first and second deep element isolation patterns DTI1 and DTI2 may form a substantial grid shape in a plan view. Each of the pixel regions PXRa may be or may correspond to or include (or be included in) a portion of the substrate 100 surrounded by the first and second deep element isolation patterns DTI1 and DTI2.

A shallow element isolation pattern STI may be provided in the substrate 100 to define a plurality of active regions in each of the pixel region groups PXRGa. The shallow element isolation pattern STI may fill a shallow trench recessed from the one surface of the substrate 100. For example, the shallow element isolation pattern STI may be provided in the substrate 100 and may be adjacent to the one surface of the substrate 100. Each of the active regions may be a portion of the substrate 100 (for example, a portion of the pixel region PXRa) surrounded by the shallow element isolation pattern STI in a plan view.

The plurality of active regions may include a first active region ATR1, a second active region ATR2, a third active region, and a fourth active region. The source follower transistor SFX may be provided in the first active region ATR1, and the transfer transistor TX may be provided in the second active region ATR2. The reset transistor RX may be provided in the third active region, and the selection transistor SX may be provided in the fourth active region. More specifically, the source follower gate SFGa may be disposed on the first active region ATR1, and the transfer gate TG may be disposed on the second active region ATR2. The reset gate RG may be disposed on the third active region, and the selection gate SG may be disposed on the fourth active region.

In some example embodiments, the first active region ATR1 may be located in any one of the pixel regions PXRa of each of the pixel region groups PXRGa. Referring to FIG. 5, in some example embodiments, each of the pixel region groups PXRGa may include first to fourth pixel regions PXR1a, PXR2a, PXR3a, and PXR4a, and the first active region ATR1 may be defined in the first pixel region PXR1a.

In some example embodiments, the second active region ATR2 may be defined in each of the pixel regions PXRa of each of the pixel region groups PXRGa. For example, as shown in FIG. 5, the second active regions ATR2 may be each defined in the first to fourth pixel regions PXR1a to PXR4a. In this case, the transfer gates TG may respectively be disposed on the second active regions ATR2. In some example embodiments, the second active regions ATR2 of each of the pixel region groups PXRGa may extend and may be connected to each other.

The third active region may be defined in another one of the pixel regions PXRa of each of the pixel region groups PXRGa, and the fourth active region may be defined in still another one of the pixel regions PXRa of each of the pixel region groups PXRGa. For example, as shown in FIG. 5, the third active region may be defined in the second pixel region PXR2a, and the fourth active region may be defined in the fourth pixel region PXR4a. In some example embodiments, an additional transistor may be provided in another active region defined in the third pixel region PXR3a. The additional transistor may be a dummy transistor and in some cases may not be electrically active during operation of the image sensor, e.g., may be floating or electrically insulated, or may be a transistor (for example, a dual conversion gain transistor) performing an additional function.

The floating diffusion region FD may be provided in the second active region ATR2 at one side of the transfer gate TG. The floating diffusion regions FD of each of the pixel region groups PXRGa may extend along the second active regions ATR2 and may be connected to each other.

A photoelectric conversion region 60 may be provided in each of the pixel regions PXRa. The substrate 100 (that is, each of the pixel regions PXRa) may be doped with impurities having a first conductivity type, and the photoelectric conversion region 60 may be doped with impurities having a second conductivity type different from the first conductivity type. One of the first conductivity type and the second conductivity type may be a P-type, and the other one of the first conductivity type and the second conductivity type may be an N-type. For example, the first conductivity type may be the P-type and in some cases may be doped with P-type impurities such as but not limited to boron, and the second conductivity type may be the N-type and in some cases may be doped with N-type impurities such as but not limited to arsenic and/or phosphorus. Accordingly, the photoelectric conversion region 60 and the pixel region PXRa surrounding the photoelectric conversion region 60 may configure a photodiode by being PN-junctioned or forming a PN-junction. The floating diffusion region FD may be doped with impurities having the second conductivity type.

Referring to FIG. 6, the source follower gate SFG may include a pair of first vertical portions 310a, respectively filling a pair of first gate recesses GR1 provided in the first active region ATR1. The transfer gate TG may include a pair of second vertical portions 410, respectively filling a pair of second gate recesses GR2 provided in the second active region ATR2. The pair of first gate recesses GR1 may be laterally spaced apart from each other and recessed from an upper surface of the first active region ATR1 in a depth direction (for example, vertically) of the substrate 100. The pair of second gate recesses GR2 may be laterally spaced apart from each other and recessed from an upper surface of the second active region ATR2 in the depth direction (that is, vertically) of the substrate 100.

In some example embodiments, a depth of the first gate recess GR1 may be substantially the same as a depth of the second gate recess GR2. In some example embodiments, the depths of the first and second gate recesses GR1 and GR2 may be smaller than a depth of the shallow trench. However, the depths of the first and second gate recesses GR1 and GR2 are not limited thereto, and may also be larger than the depth of the shallow trench.

A source follower channel region 330a may be defined between the pair of first gate recesses GR1. The source follower channel region 330a may be a portion of the first active region ATR1 (for example, a portion of the substrate 100) located between the pair of first gate recesses GR1. For example, the source follower channel region 330a may be located between the pair of first vertical portions 310a. In some example embodiments, the pair of first vertical portions 310a may be in contact with the shallow element isolation pattern STI.

A width W_{SFC} of the source follower channel region 330a may decrease in a depth direction of the first gate recess GR1. The width W_{SFC} of the source follower channel region 330a may be defined in a direction in which the pair of first gate recesses GR1 are spaced apart from each other. More specifically, the width W_{SFC} of the source follower channel region 330a may be defined in a direction perpendicular to a longitudinal direction of the source follower channel region 330a.

In some example embodiments, the source follower channel region 330a may be spaced apart from the substrate 100. In some example embodiments, the substrate 100 may include a protrusion 110 (first protrusion) protruding toward the source follower channel region 330a. The protrusion 110 may be defined by the pair of first gate recesses GR1. For example, the protrusion 110 may be located between the pair of first vertical portions 310a. The protrusion 110 may be spaced apart from the source follower channel region 330a. Specifically, the protrusion 110 and the source follower channel region 330a may be vertically spaced apart from each other.

A width of the protrusion 110 may increase in the depth direction of the first gate recess GR1. For example, the width of the protrusion 110 may decrease toward the source follower channel region 330a. In some example embodiments, the maximum width of the protrusion 110 may differ from the maximum width of the source follower channel region 330a.

A first gate insulating film 340a may be disposed between the source follower channel region 330a and the first vertical portions 310a of the source follower gate SFGa. The first gate insulating film 340a may extend and be disposed between the protrusion 110 and the first vertical portions 310a.

In some example embodiments, the first gate insulating film 340a may extend and be disposed between the source follower channel region 330a and the protrusion 110. In some example embodiments, the first gate insulating film 340a may completely fill a space between the source follower channel region 330a and the protrusion 110. For example, the first gate insulating film 340a between the source follower channel region 330a and the protrusion 110 may be in contact with a lower end of the source follower channel region 330a and an upper end of the protrusion 110.

The first gate insulating film 340a may extend and be disposed between the substrate 100 and the pair of first vertical portions 310a. For example, the first gate insulating film 340a may be formed so that the substrate 100 is spaced apart from the pair of first vertical portions 310a.

The source follower gate SFGa may further include a first horizontal portion 320a connected to the pair of first vertical portions 310a. Specifically, the first horizontal portion 320a may be connected to upper ends of the pair of first vertical portions 310a. The first horizontal portion 320a may cover an upper surface of the source follower channel region 330a, and the first gate insulating film 340a may extend and be disposed between the first horizontal portion 320a and the source follower channel region 330a. The first horizontal portion 320a may laterally extend to cover a portion of the shallow element isolation pattern STI.

A transfer channel region 430 may be defined between the pair of second gate recesses GR2. The transfer channel region 430 may include a first portion 431 and a second portion 432 that are vertically stacked and connected to each other. The first portion 431 and the second portion 432 may form a single body without a boundary surface therebetween. A width of the first portion 431 may gradually decrease toward the second portion 432, and a width of the second portion 432 may gradually decrease toward the first portion 431. For example, a width W_{TC} of the transfer channel region 430 may gradually decrease and then gradually increase in a depth direction of the second gate recess GR2. For example, as shown in FIG. 6, the transfer channel region 430 may have an hourglass-shaped cross-section. The transfer channel region 430 (for example, the first portion 431) may be connected to, e.g., seamlessly connected to, the substrate 100. Specifically, the transfer channel region 430 and the substrate 100 may configure a single body without a boundary surface or interfaces therebetween. For example, a channel formed in the first and second portions 431 and 432 of the transfer channel region 430 may be electrically connected to the photoelectric conversion region 60 through the substrate 100.

The maximum width of the transfer channel region 430 may be larger than the maximum width of the source follower channel region 330a. For example, a width of an upper surface of the transfer channel region 430 may be larger than a width of the upper surface of the source follower channel region 330a. Alternatively or additionally, the minimum width of the transfer channel region 430 may be larger than the minimum width of the source follower channel region 330a. For example, a width of a connecting portion between the first and second portions 431 and 432 of the transfer channel region 430 may be larger than the width of the lower end of the source follower channel region 330a.

A second gate insulating film 440 may be disposed between the transfer channel region 430 and the second vertical portions 410 of the transfer gate TG. The transfer gate TG may further include a second horizontal portion 420 connected to the pair of second vertical portions 410. The second horizontal portion 420 may cover the upper surface of the transfer channel region 430, and the second gate insulating film 440 may extend and be disposed between the second horizontal portion 420 and the upper surface of the transfer channel region 430.

In some example embodiments, gates TG, SFG, RG, and SG may be formed of or may include the same conductive material. For example, the gates TG, SFG, RG, and SG may include at least one of a doped semiconductor material (e.g., doped polysilicon), a metal (e.g., tungsten, titanium, aluminum, tantalum, etc.), a conductive metal nitride (e.g., one or more of titanium nitride, tantalum nitride, etc.), or a conductive metal-semiconductor compound (e.g., metal silicide, etc.). In some example embodiments, the first and second gate insulating films 340a and 440 may be formed of the same insulating material. For example, the first and second gate insulating films 340a and 440 may include at least one of a silicon oxide, a silicon oxynitride, a silicon nitride, or a high-k dielectric.

In the above-described example embodiments, the source follower gate SFGa may cover the upper surface and side surfaces of the source follower channel region 330a that has a width gradually decreasing toward a lower end thereof. Accordingly, the channel width of the source follower transistor SFX including the source follower gate SFGa can be increased per unit area. Alternatively or additionally, the transfer gate TG may also cover the upper surface and both side surfaces of the transfer channel region 430, and accordingly, the channel width of the transfer transistor TX including the transfer gate TG can be also increased per unit area. As a result, the performance of the source follower transistor SFX and the transfer transistor TX can be improved. In particular, a signal-to-noise ratio (SNR) of the source follower transistor SFX can be improved due to the increased channel width of the source follower transistor SFX.

Alternatively or additionally, the source follower channel region 330a may be spaced apart from the substrate 100, but the transfer channel region 430 may be connected to such as seamlessly connected to the substrate 100. Therefore, when the image sensor operates, the photocharges generated in the photoelectric conversion region 60 may move to the floating diffusion region FD through the channel of the transfer transistor TX.

As shown in FIG. 5, structures of the reset gate RG and the selection gate SG may be substantially the same as a structure of the source follower gate SFGa. However, some example embodiments are not limited thereto. In some example embodiments, at least one of the reset gate RG or the selection gate SG may be a planar type gate.

Meanwhile, in the above-described example embodiments, each of the pixel group regions PXRGa may include a plurality of pixel regions PXRa. However, some example embodiments are not limited thereto. In some example embodiments, each of the pixel region groups PXRGa may have a single pixel region PXRa. In this case, the pixel region group PXRGa may correspond to the pixel region PXRa, and the second deep element isolation pattern DTI2 may be omitted. In this case, the above-described first to fourth active regions may be defined in each of the pixel regions PXRa. For example, the pixel transistors TX, RX, SFX, and SX, the floating diffusion region FD, and the photoelectric conversion element PD may be formed in each of the pixel regions PXRa. In this case, the image sensor of FIG. 2 may be implemented.

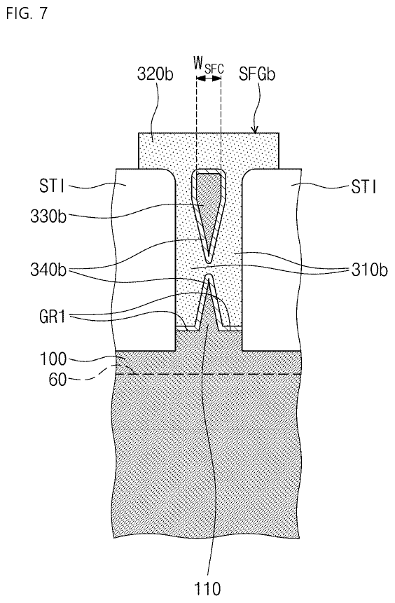

FIG. 7 shows an image sensor according to some example embodiments, which is a cross-sectional view corresponding to line I-I′ of FIG. 5.

Referring to FIG. 7, in some example embodiments, a first gate insulating film 340b on a surface of a source follower channel region 330b may be spaced apart from a first gate insulating film 340b on a surface of a protrusion 110. For example, the first gate insulating film 340b on a lower end of the source follower channel region 330b may be spaced apart from the first gate insulating film 340b on an upper end of the protrusion 110. As a result, a space may be defined between the first gate insulating film 340b on the lower end of the source follower channel region 330b and the first gate insulating film 340b on the upper end of the protrusion 110. In this case, a pair of first vertical portions 310b may extend into the space and be connected to each other. As a result, a source follower gate SFGb may completely surround the source follower channel region 330b in a cross-sectional view.

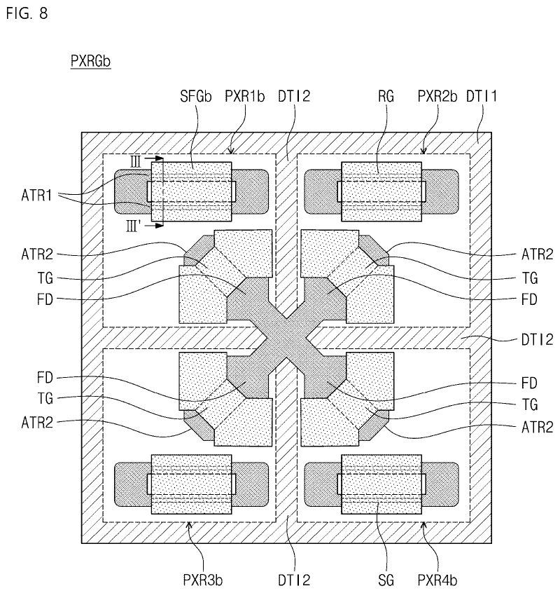

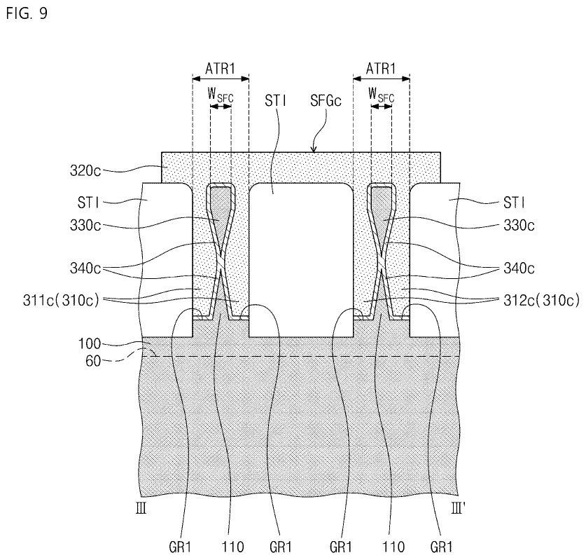

FIG. 8 is a plan view of an image sensor according to some example embodiments. FIG. 9 is a cross-sectional view taken along line III-III′ of FIG. 8.

Referring to FIGS. 8 and 9, in some example embodiments, a plurality of first active regions ATR1 may be defined in one of pixel regions PXR1b to PXR4b of each of pixel region groups PXRGb by a shallow element isolation pattern STI and may be adjacent to each other. A source follower gate SFGc may be disposed on the plurality of first active regions ATR1.

The source follower gate SFGc may include a pair of first vertical portions 310c, respectively filling a pair of first gate recesses GR1 provided in each of the first active regions ATR1. For example, the pair of first vertical portions 310c may be defined as vertical portion groups, and the source follower gate SFGc may include vertical portion groups 311c and 312c respectively disposed in the first active regions ATR1. A source follower channel region 330c may be defined between the pair of first vertical portions 310c formed in each of the first active regions ATR1. Referring to FIG. 9, in some example embodiments, the source follower gate SFGc may include two vertical portion groups 311c and 312c, and the vertical portion groups 311c and 312c may be disposed in the two first active regions ATR1, respectively. In addition, two source follower channel regions 330c may be defined in the two first active regions ATR1, respectively.

A first horizontal portion 320c of the source follower gate SFGc may be connected to the first vertical portions 310c in the plurality of first active regions ATR1 and may cover upper surfaces of the plurality of source follower channel regions 330c. A first gate insulating film 340c may be disposed between the source follower gate SFGc and the source follower channel regions 330c.

First end portions of the first active regions ATR1 provided at one side of the source follower gate SFGc may extend and be connected to each other, and second end portions of the first active regions ATR1 provided at the other side of the source follower gate SFGc may extend and be connected to each other. Accordingly, a first source/drain region may be provided in the connected first end portions, and a second source/drain region may be provided in the connected second end portions.

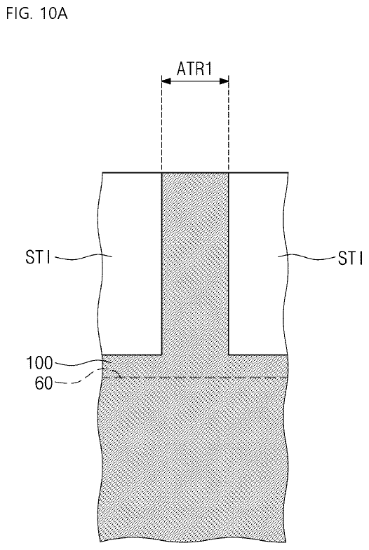

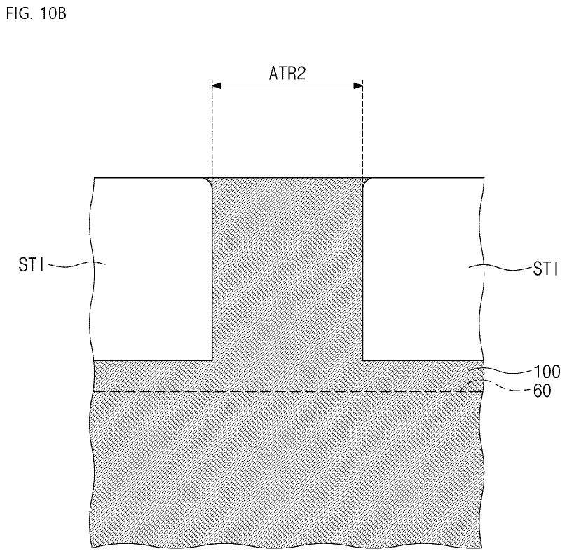

FIGS. 10A, 11A, 12A, 13A, and 14A show a manufacturing method of an image sensor according to some example embodiments, which are cross-sectional views corresponding to line I-I′ of FIG. 5. FIGS. 10B, 11B, 12B, 13B, and 14B show a manufacturing method of an image sensor according to some example embodiments, which are cross-sectional views corresponding to line II-II′ of FIG. 5.

Referring to FIGS. 10A and 10B, a shallow element isolation pattern STI may be formed in a substrate 100 to define active regions. For example, a patterning process may be performed on one surface of the substrate 100 to form a shallow trench, and the shallow element isolation pattern STI may be formed to fill the shallow trench.

The patterning process may include a photolithography process, an etch process, and a deposition process; example embodiments are not limited thereto. In some cases, the etch process may be or may include a wet and/or a dry etching process; example embodiments are not limited thereto. In some cases, the deposition process may include one or more of a chemical vapor deposition process or a spin-on process; example embodiments are not limited thereto.

Each of the first and second deep element isolation patterns DTI1 and DTI2 (see FIGS. 4 and 5) may be formed in the substrate 100 to define the pixel region groups PXRGa including the plurality of pixel regions PXRa. Photoelectric conversion regions 60 may be formed in the pixel regions PXRa, respectively. For example, the photoelectric conversion regions 60 may be formed using an implantation process such as a beamline ion implantation process; example embodiments are not limited thereto. In some example embodiments, the photoelectric conversion regions 60 may be formed or at least partially formed before the formation of the first and second deep element isolation patterns DTI1 and DTI2 and the shallow element isolation pattern STI. Alternatively or additionally, the photoelectric conversion regions 60 may be formed or at least partially formed after the formation of the first and second deep element isolation patterns DTI1 and DTI2. In some example embodiments, the first and second deep element isolation patterns DTI1 and DTI2 may be formed after the formation of the shallow element isolation pattern STI.

A plurality of active regions may be defined in each of the pixel region groups PXRGa. As described above, the active regions of each of the pixel region groups PXRGa may include a first active region ATR1 and a second active region ATR2.

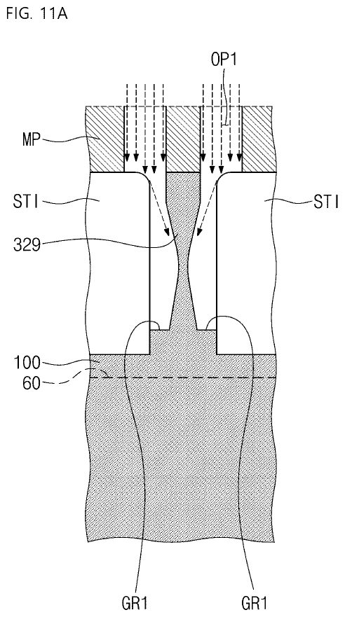

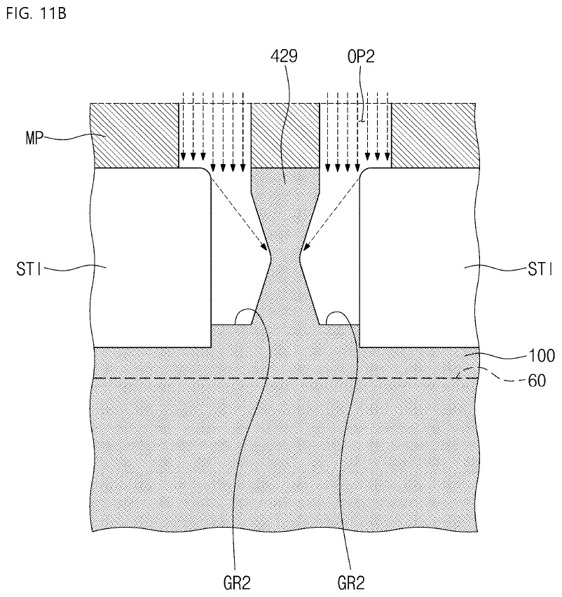

Referring to FIGS. 11A and 11B, a mask pattern MP may be formed on one surface of the substrate 100, e.g., with a photolithographic process. The mask pattern MP may have a pair of first openings OP1 and a pair of second openings OP2. The pair of first openings OP1 may define a pair of first gate recesses GR1, and the pair of second openings OP2 may define a pair of second gate recesses GR2.

More specifically, the pair of first openings OP1 may be spaced apart from each other and may respectively expose portions of the first active region ATR1. In some example embodiments, each of the pair of first openings OP1 may also expose a portion of the shallow element isolation pattern STI adjacent to the portion of the first active region ATR1. This may be helpful for alignment margin. The pair of second openings OP2 may be spaced apart from each other and may respectively expose portions of the second active region ATR2. In some example embodiments, each of the pair of second openings OP2 may also expose a portion of the shallow element isolation pattern STI adjacent to the portion of the second active region ATR2. In some example embodiments, an interval between the pair of first openings OP1 may be smaller than an interval between the pair of second openings OP2.

An etching process, such as an anisotropic etching process or at least partially anisotropic etching process, may be performed using the mask pattern MP as an etching mask to etch the first and second active regions ATR1 and ATR2. Accordingly, the pair of first gate recesses GR1 may be formed in the first active region ATR1, and the pair of second gate recesses GR2 may be formed in the second active region ATR2. The pair of first gate recesses GR1 may be formed under the pair of first openings OP1, respectively, and the pair of second gate recesses GR2 may be formed under the pair of second openings OP2, respectively.

A first channel portion 329 may be defined between the pair of first gate recesses GR1, and a second channel portion 429 may be defined between the pair of second gate recesses GR2. The first channel portion 329 may be a portion of the first active region ART1 (e.g., a portion of the substrate 100), and the second channel portion 429 may be a portion of the second active region ATR2 (i.e., a portion of the substrate 100). As described above, since the interval between the pair of first openings OP1 may be smaller than the interval between the pair of second openings OP2, a width of an upper surface of the first channel portion 329 may be smaller than a width of an upper surface of the second channel portion 429.

The etching process may be an anisotropic etching process. In some example embodiments, etching ions used in the etching process may have etching selectivity for the shallow element isolation pattern STI. For example, etch rates of the first and second active regions ATR1 and ATR2 by the etching ions may be higher than an etch rate of the shallow element isolation pattern STI by the etching ions. For example, the etch rates of the first and second active regions ATR1 and ATR2 by the etching ions may be about three times or more the etch rate of the shallow element isolation pattern STI by the etching ions.

During the etching process, some of the etching ions may collide with a side surface of the shallow element isolation pattern STI, and traveling directions of the collided etching ions may be changed. An undercut region may be formed at a middle portion of each of the first and second channel portions 329 and 429 by the collided etching ions. Accordingly, as shown in FIGS. 11A and 11B, each of the first and second channel portions 329 and 429 may have an hourglass-shaped cross-section. For example, each of the first and second channel portions 329 and 429 may have the middle portion having a width smaller than widths of its upper and lower portions.

In FIG. 11A, the first channel portion 329 may have upper, lower, and middle portions that are connected to each other. However, some example embodiments are not limited thereto. In some example embodiments, the middle portion of the first channel portion 329 may be removed by the etching process, and the upper and lower portions of the first channel portion 329 may be spaced apart from each other after the etching process. However, even in this case, since a width of the second channel portion 429 is larger than a width of the first channel portion 329, the second channel portion 429 may have upper, middle, and lower portions that are connected to each other.

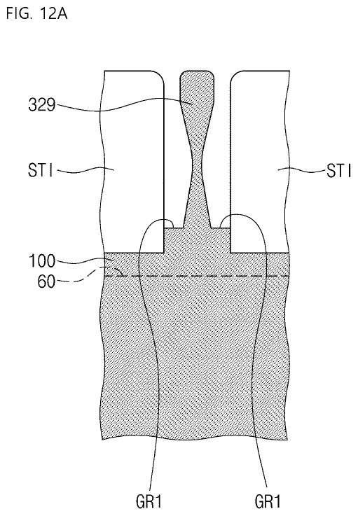

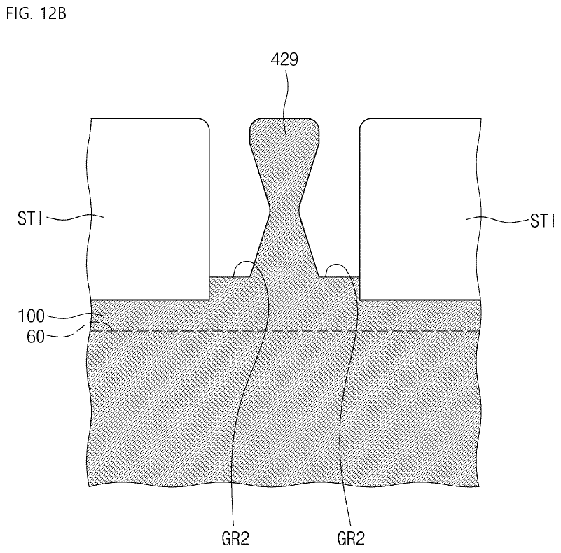

Referring to FIGS. 12A and 12B, the mask pattern MP may be removed after the etching process, e.g., removed with an ashing process. Thereafter, a sacrificial oxidation process may be performed on the substrate 100. The sacrificial oxidation process may be performed to cure the etched surface of the substrate 100. For example, the sacrificial oxidation process may be performed on the substrate 100 to oxidize exposed surfaces of the first and second channel portions 329 and 429 and bottom surfaces of the first and second gate recesses GR1 and GR2. Accordingly, a sacrificial oxide film may be formed on the exposed surfaces and the bottom surfaces. Subsequently, the sacrificial oxide film may be removed by an isotropic etching process (for example, a wet etching process, such as a wet etching process using an oxide etchant such as buffered hydrogen fluoride). Therefore, the surfaces of the first and second channel portions 329 and 429 and the bottom surfaces of the first and second gate recesses GR1 and GR2 may be cured.

The widths of the first and second channel portions 329 and 429 may be decreased by the sacrificial oxidation process and the removal process of the sacrificial oxide film. In FIG. 12A, the first channel portion 329 may have upper, middle, and lower portions that are connected to each other. However, some example embodiments are not limited thereto. In some example embodiments, the middle portion of the first channel portion 329 may be removed by the sacrificial oxidation process and the removal process of the sacrificial oxide film, and the upper and lower portions of the first channel portion 329 may be spaced apart from each other. However, even in this case, the second channel portion 429 may have lower, middle, and upper portions that are connected to each other.

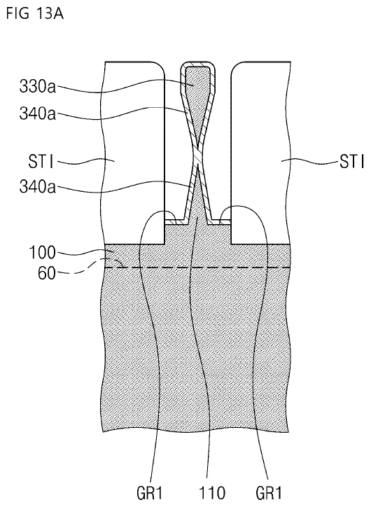

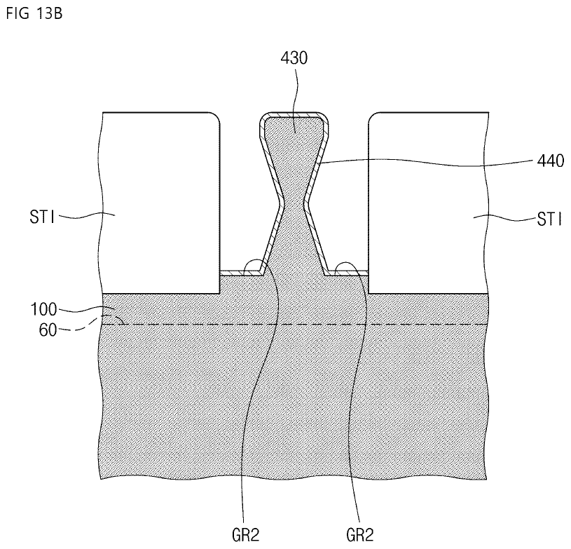

Referring to FIGS. 13A and 13B, a first gate insulating film 340a may be formed on the first active region ATR1, and a second gate insulating film 440 may be formed on the second active region ATR2. In some example embodiments, the first and second gate insulating films 340a and 440 may be formed using an oxidation process such as but not limited to a thermal oxidation process. Since the first and second gate insulating films 340a and 440 are formed, the first channel portion 329 may be separated into a source follower channel region 330a and a protrusion 110, and the second channel portion 429 may be formed as a transfer channel region 430. Specifically, the middle portion of the first channel portion 329 may be completely oxidized by the oxidation process to be formed as the first gate insulating film 340a, and accordingly, the upper and lower portions of the first channel portion 329 may be spaced apart from each other. In this case, the upper portion of the first channel portion 329 may correspond to the source follower channel region 330a, and the lower portion of the first channel portion 329 may correspond to the protrusion 110. As a result, the first gate insulating film 340a may be formed on a surface of the source follower channel region 330a, a surface of the protrusion 110, and the bottom surfaces of the first gate recesses GR1, and the second gate insulating film 440 may be formed on a surface of the transfer channel region 430 and the bottom surfaces of the second gate recesses GR2.

The first and second gate insulating films 340a and 440 may be formed simultaneously, e.g., within one furnace or within one furnace. In some example embodiments, the first and second gate insulating films 340a and 440 may include not only an oxide film formed by the oxidation process but also an insulating film (e.g., a silicon nitride film and/or a high-k dielectric film) formed by a deposition process.

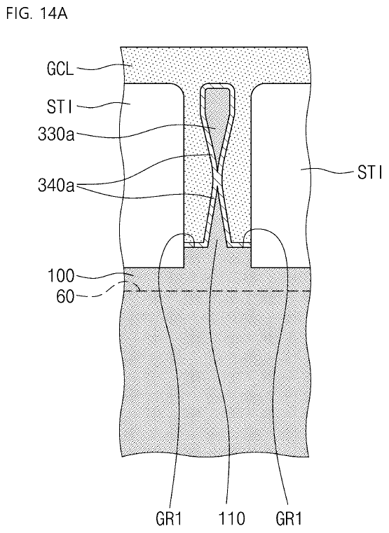

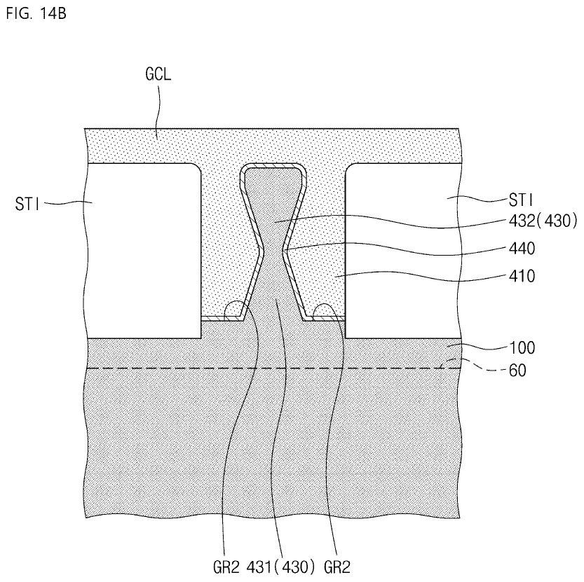

Referring to FIGS. 14A and 14B, a gate conductive layer GCL may be formed on one surface of the substrate 100 having the first and second gate insulating films 340a and 440. The gate conductive layer GCL may fill the first and second gate recesses GR1 and GR2. For example, the gate conductive layer GCL may be made of at least one material of a doped semiconductor material (e.g., doped polysilicon), a metal (e.g., one or more of tungsten, titanium, aluminum, tantalum, etc.), a conductive metal nitride (e.g., titanium nitride, tantalum nitride, etc.), or a conductive metal-semiconductor compound (e.g., metal silicide, etc.). The gate conductive layer GCL may be formed with a deposition process such as but not limited to a plasma-enhanced chemical vapor deposition (PECVD) process; example embodiments are not limited thereto.

Referring again to FIG. 6, the gate conductive layer GCL may be patterned to form the source follower gate SFGa and the transfer gate TG. Thereafter, interlayer insulating films, contact plugs, and wiring layers including wirings may be formed on the one surface of the substrate 100, and the other surface of the substrate 100 may be ground to expose bottom surfaces of the first and second deep element isolation patterns DTI1 and DTI2. Subsequent processes for the image sensor may also be performed.

According to the above-described manufacturing method, the transfer channel region 430 connected to or seamlessly connected to the substrate 100 and the source follower channel region 330a spaced apart from the substrate 100 may be formed simultaneously by substantially the same processes. Therefore, the manufacturing processes for the image sensor can be simplified, and the process difficulty of the image sensor can be reduced. As a result, the manufacturing cost of the image sensor can be reduced.

FIG. 15 is a cross-sectional view of an image sensor according to some example embodiments.

Referring to FIG. 15, an image sensor according to some embodiment of the present disclosure may include a first structure S1 and a second structure S2. The first structure S1 may be stacked on the second structure S2. For example, the image sensor may have a stacked structure. The first structure S1 may be referred to as a sensor chip or a first chip. The second structure S2 may be referred to as a logic chip or a second chip. The first structure S1 and the second structure S2 may be bonded to each other by at least one of various bonding methods and electrically connected to each other by at least one of various connection methods.

The first structure S1 may include a photoelectric conversion layer 10, a light-transmitting layer 20, and a first wiring layer 30. The photoelectric conversion layer 10 may be disposed between the light-transmitting layer 20 and the first wiring layer 30. The photoelectric conversion layer 10 may include a first substrate 100. The first substrate 100 may have a first surface 100a and a second surface 100b that face each other. In some example embodiments, the first substrate 100 may be or may include a semiconductor substrate (for example, one or more of a silicon (Si) substrate, a germanium (Ge) substrate, or a silicon-germanium (SiGe) substrate).

A deep element isolation pattern DTI may be provided in the first substrate 100 to define a plurality of pixel regions PXR.

A shallow element isolation pattern STI may be provided in the first substrate 100 to define at least one active region in each of the pixel regions PXR. The shallow element isolation pattern STI may be adjacent to the first surface 100a of the first substrate 100. The first surface 100a of the first substrate 100 may correspond to one surface of the above-mentioned substrate 100.

Photoelectric conversion regions 60 may be provided in the pixel regions PXR, respectively. The first substrate 100 may be doped with dopants having a first conductivity type, and the photoelectric conversion regions 60 may be doped with dopants having a second conductivity type different from the first conductivity type. For example, the first conductivity type may be a P-type, and the second conductivity type may be an N-type.

A transfer gate TG may be provided in the corresponding active region of each of the pixel regions PXR. A gate dielectric film may be disposed between the transfer gate TG and the corresponding active region. In some example embodiments, the transfer gate TG may fill a second gate recess GR2 formed in the corresponding active region. In this case, the gate dielectric film may extend to be disposed between the transfer gate TG and an inner surface of the second gate recess GR2.

In some example embodiments, other gates (not shown) may be provided on the active regions with the corresponding gate dielectric film interposed therebetween. The other gates may include a reset gate, a source follower gate, and a selection gate. In some example embodiments, the other gates may further include a gate performing another function (e.g., a dual conversion gain gate). Source/drain regions may be provided at both sides of each of the other gates. The other gates may be provided on the corresponding active regions of each of the pixel regions PXR. Alternatively or additionally, all or at least some of the other gates may be provided on the corresponding active regions of the pixel regions PXR of the pixels sharing the other gates.

As described above, the transfer gate TG and the other gates may be provided on the first surface 100a of the first substrate 100. However, some example embodiments are not limited thereto. In some example embodiments, the transfer gate TG may be provided on the first surface 100a of the first substrate 100, and the other gates may be provided on an additional substrate (e.g., a third substrate 103). The additional substrate may have a third surface facing the first surface 100a and a fourth surface opposite to the third surface. The other gates (for example, the source follower gate SFG, the reset gate RG, and the selection gate SG) may be provided on the third surface or the fourth surface of the additional substrate with an additional gate insulating film (for example, a third interlayer insulating film ILD3) interposed therebetween. An intermediate structure (for example, a third structure S3) including the additional substrate and the other gates may be provided between the first structure S1 and the second structure S2, and the intermediate structure may be bonded to the first and second structures S1 and S2 by at least one of various bonding methods. Hereafter, for convenience of explanation, the embodiment in which the transfer gate TG and the other gates are provided on the first surface 100a of the first substrate 100 will be continuously described as an example.

The deep element isolation pattern DTI, the shallow element isolation pattern STI, the photoelectric conversion regions 60, the floating diffusion regions FD, and the transfer gates TG may be included in the photoelectric conversion layer 10.

The light-transmitting layer 20 may be provided on the second surface 100b of the first substrate 100. The light-transmitting layer 20 may include a transmission insulating film 510, a grid pattern 520, a protective film 530, color filters CF1, CF2, and CF3, and micro lenses ML.

The transmission insulating film 510 may cover the second surface 100b of the first substrate 100. The transmission insulating film 510 may have a single-layered structure or a multi-layered structure. In some example embodiments, the transmission insulating film 510 may include a fixed charge film and/or an anti-reflection film.

The fixed charge film may have negative fixed charges. Therefore, holes may be accumulated at a location adjacent to the fixed charge film, for example, at an interface between the fixed charge film and the first substrate 100 and/or in a portion of the first substrate 100 adjacent to the second surface 100b. As a result, the fixed charge film can effectively reduce a dark current and/or a white spot. In some example embodiments, the fixed charge film may be made of a metal oxide or a metal fluoride containing at least one of hafnium Hf, zirconium Zr, aluminum Al, tantalum Ta, titanium Ti, yttrium Y, or a lanthanide. For example, the fixed charge film may be made of a hafnium oxide or an aluminum oxide.

The anti-reflection film can reduce or minimize reflection of light incident on the second surface 100b. For example, the anti-reflection film may include at least one of a titanium oxide, a silicon nitride, a silicon oxide, or a hafnium oxide. When the transmission insulating film 510 includes the fixed charge film and the anti-reflection film, the fixed charge film may be in contact with the second surface 100b of the first substrate 100, and the anti-reflection film may be disposed on the fixed charge film. However, some example embodiments are not limited thereto. In some example embodiments, the transmission insulating film 510 may include any one of the fixed charge film and the anti-reflection film, or may further include an additional insulating film.

The grid pattern 520 may have a grid shape with openings in a plan view. In some example embodiments, the openings of the grid pattern 520 may vertically overlap the pixel regions PXR, respectively. The grid pattern 520 may guide incident light so that the incident light is incident into the photoelectric conversion regions 60. In some example embodiments, the grid pattern 520 may include a light-shielding pattern and/or a low refractive pattern. For example, the light-shielding pattern may include at least one of titanium, titanium nitride, tantalum, tantalum nitride, or tungsten. The low refractive pattern may have a refractive index lower than the refractive indices of the color filters CF1, CF2, and CF3. For example, the low refractive pattern may include an organic material.

The protective film 530 may conformally cover a surface (e.g., an upper surface and side surfaces) of the grid pattern 520 and the transmission insulating film 510 exposed by the openings of the grid pattern 520. In some example embodiments, the protective film 530 may be made of an insulating material having a high dielectric constant. For example, the protective film 530 may include an aluminum oxide or a hafnium oxide.

The color filters CF1, CF2, and CF3 may fill the openings of the grid pattern 520. The color filters CF1, CF2, and CF3 may be disposed on the protective film 530. The color filters CF1, CF2, and CF3 may vertically overlap the photoelectric conversion regions 60. In some example embodiments, the color filters CF1, CF2, and CF3 may include a first color filter CF1 having a first color, a second color filter CF2 having a second color, and a third color filter CF3 having a third color. In some example embodiments, the first color may be one of red, green, and blue colors, the second color may be another of red, green, and blue colors, and the third color may be the remaining one of red, green, and blue colors. Alternatively, the first color may be one of magenta, cyan, and yellow colors, the second color may be another of magenta, cyan, and yellow colors, and the third color may be the remaining one of magenta, cyan, and yellow colors. However, some example embodiments are not limited thereto. The first to third colors may be various other colors.

As shown in FIG. 15, each of the color filters CF1, CF2, and CF3 may vertically overlap a corresponding one of the photoelectric conversion regions 60. However, some example embodiments are not limited thereto. In some example embodiments, each of the color filters CF1, CF2, and CF3 may vertically overlap the plurality of photoelectric conversion regions 60 that are adjacent to each other. The photoelectric conversion regions 60 corresponding to each of the color filters CF1, CF2, and CF3 may be arranged in a matrix form. For example, the corresponding photoelectric conversion regions 60 may be arranged in a 2×2 matrix form, a 3×3 matrix form, or a 4×4 matrix form.

The micro lenses ML may be provided on the color filters CF1, CF2, and CF3. The micro lenses ML may condense incident light. As shown in FIG. 15, the micro lenses ML may vertically overlap the photoelectric conversion regions 60. Alternatively, each of the micro lenses ML may vertically overlap the plurality of photoelectric conversion regions 60 that are adjacent to each other. For example, each of the micro lenses ML may vertically overlap the photoelectric conversion regions 60 arranged in a 2×2 matrix form, a 3×3 matrix form, or a 4×4 matrix form. In some example embodiments, the number of photoelectric conversion regions 60 overlapping at least one of the micro lenses ML may differ from the number of photoelectric conversion regions 110 overlapping at least another one of the micro lenses ML. For example, the at least one micro lens ML may vertically overlap a pair of photoelectric conversion regions 60 that are adjacent to each other, and the at least another micro lens ML may vertically overlap a single photoelectric conversion region 60 or the photoelectric conversion regions 60 that are adjacent to each other.

Each of the micro lenses ML may have a shape that is convex upward in a plan view. In some example embodiments, each of the micro lenses ML may have a circular shape or an elliptical shape in a plan view. The micro lenses ML may be made of a light-transmitting resin.

Although not shown, an additional protective film may be provided on surfaces of the micro lenses ML. The additional protective film may protect the micro lenses ML and transmit light. The additional protective film may be made of an organic material and/or an inorganic material. For example, the additional protective film may include at least one of a silicon oxide, a silicon nitride, a silicon oxynitride, a silicon carbide, a silicon carbo-oxide, a silicon carbo-nitride, a silicon carbo-oxynitride, an aluminum oxide, a zinc oxide, or a hafnium oxide.

As shown in FIG. 15, the grid pattern 520 may be vertically aligned with the deep trench isolation DTI, and the micro lens ML and the color filter CF1 or CF2 may be vertically aligned with the corresponding photoelectric conversion region 60. However, some example embodiments are not limited thereto.

The first wiring layer 30 may be provided on the first surface 100a of the first substrate 100. The first wiring layer 30 may cover the first surface 100a of the first substrate 100 and include first interlayer insulating films ILD1 and first wiring lines ICL1. The first wiring lines ICL1 may be provided between the first interlayer insulating films ILD1. The first wiring lines ICL1 may be electrically connected to pixel transistors (e.g., the transfer transistor, the reset transistor, the source follower transistor, and the selection transistor) and/or may electrically connect the pixel transistors through first contact plugs.

The second structure S2 may include a second substrate 102, peripheral transistors PTR formed on an upper surface of the second substrate 102, and a second wiring layer 40 provided on the upper surface of the second substrate 102 to cover the peripheral transistors PTR. A size, arrangement, number of layers, thickness, etc. of each of the peripheral transistors PTR and the second wiring layer 40 is not limited to the features illustrated in FIG. 15. The second substrate 102 may be a semiconductor substrate such as a silicon substrate, germanium substrate, or silicon-germanium substrate. The second wiring layer 40 may include second interlayer insulating films ILD2 and second wiring lines ICL2 between the second interlayer insulating films ILD2. The second wiring lines ICL2 may be electrically connected to the peripheral transistors PTR or may electrically connect the peripheral transistors PTR through second contact plugs. The second wiring lines ICL2 and the peripheral transistors PTR may configure peripheral circuits (e.g., one or more of a row decoder, a row driver, a column decoder, a timing generator, a correlated double sampler, an analog-to-digital converter, and/or an input/output buffer) of the image sensor.

The first structure S1 may be stacked on the second structure S2, and the first and second structures S1 and S2 may be bonded to each other. The second wiring layer 40 may be disposed between the first wiring layer 30 and the second substrate 102. In some example embodiments, the lowermost one of the first interlayer insulating films ILD1 may be bonded to the uppermost one of the second interlayer insulating film ILD2.

FIG. 16 is a cross-sectional view of an image sensor according to some example embodiments.

Referring to FIG. 16, the image sensor may include a first structure S1, a second structure S2, and a third structure S3. The third structure S3 may be disposed between the first structure S1 and the second structure S2.

The first structure S1 may include a light-transmitting layer 20, a photoelectric conversion layer 10, and a first wiring layer 30. The light-transmitting layer 20 may be the same as the light-transmitting layer 20 of FIG. 15. The photoelectric conversion layer 10 may include a transmission insulating film 510, a first substrate 100, a deep trench isolation pattern DTI, photoelectric conversion regions 60, a shallow trench isolation pattern STI, transfer gates TG, and floating diffusion regions FD. The first wiring layer 30 may include first wiring lines ICL1, first interlayer insulating films ILD1, and first bonding pads (not shown).

The second structure S2 may include a second substrate 102 and a second wiring layer ICL2 on the second substrate 102. The second structure S2 may be substantially the same as the second structure S2 of FIG. 15. However, the second structure S2 may further include second bonding pads (no reference numerals) provided in the uppermost one of second interlayer insulating films ILD2.

The third structure S3 may include a third substrate 103, gates SFG, RG, and SG on the third substrate 103, and a third wiring layer 50 provided on the third substrate 103.

The third structure S3 may be disposed between the first structure S1 and the second structure S2. Specifically, the third structure S3 may be stacked on the second structure S2, and the first structure S1 may be stacked on the third structure S3. The first, second, and third structures S1, S2, and S3 may be bonded to each other.

The third substrate 103 may be a semiconductor substrate (for example, a silicon Si substrate, a germanium Ge substrate, or a silicon-germanium SiGe substrate). Each of the gates SFG, RG, and SG may be disposed on the third substrate 103 with a gate dielectric film interposed therebetween. Source/drain regions (not shown) may be provided in the third substrate 103 at both sides of each of the gates SFG, RG, and SG. The third substrate 103 may have a third surface 103a and a fourth surface 103b that are opposite to each other. The third surface 103a may correspond to one surface of the above-described substrate 100.

A second shallow element isolation pattern STI2 may be provided in the third substrate 103 to define active regions. The second shallow element isolation pattern STI2 may be adjacent to the third surface 103a of the third substrate 103.

The third wiring layer 50 may be provided on the third surface 103a of the third substrate 103. The third wiring layer 50 may cover the third surface 103a of the third substrate 103. The third wiring layer 50 may include third interlayer insulating films ILD3, third wiring lines (no reference numerals), and at least one third bonding pad (no reference numeral).

The third wiring layer 50 may be in contact with the first wiring layer 30. The third wiring layer 50 may be electrically connected to the first wiring layer 30. The lowermost one of the first interlayer insulating films ILD1 may be bonded to the uppermost one of the third interlayer insulating films ILD3.

According to some example embodiments, the transfer gate TG may be provided in the first structure S1 and may be substantially the same as that described with reference to FIGS. 4 to 6. However, at least any one of the source follower gate SFG, the reset gate RG, or the selection gate SG may be provided on the third substrate 103. Specifically, the source follower gate SFG may be provided in the third structure S3.

The active regions of the third substrate 103 may include the first active region ATR1, the source follower channel regions 330a, 330b, and 330c, and the protrusion 110 that are described with reference to FIGS. 4 to 6, FIG. 7, or FIGS. 8 and 9.

The source follower gate SFG may include the first horizontal portions 320a, 320b, and 320c and the first vertical portions 310a, 310b, and 310c that fill the first gate recesses GR1 provided in the first active region ATR1 of the third substrate 103. In other words, the source follower gate SFG described with reference to FIGS. 4 to 6, FIG. 7, or FIGS. 8 and 9 may be provided on the third substrate 103.

The reset gate RG and the selection gate SG may be provided on the third surface 103a or the fourth surface 103b of the third substrate 103.

According to some example embodiments, the first structure S1 and the third structure S3 may be bonded to each other by a copper-to-copper bonding method, and the third structure S3 and the second structure S2 may also be bonded to each other by the copper-to-copper bonding method. For example, the bonding pads of the first, second, and third structures S1, S2, and S3 may be made of copper.

According to some example embodiments, a channel width of a source follower transistor can be increased due to a vertically extended source follower channel region. Alternatively or additionally, an area of a secured channel can be increased compared to an area of an active region on which the source follower transistor is disposed.

Alternatively or additionally, according to some example embodiments, since the channel width of the source follower transistor is increased, it is possible to reduce a noise and a leakage current of the source follower transistor. Therefore, the performance of an image sensor can be improved.

Alternatively or additionally, according to some example embodiments, an image sensor can be manufactured by utilizing an undercut phenomenon generated from an etching process. In addition, since a gate all around field-effect transistor can be manufactured without a separate additional process, the manufacturing cost of the image sensor can be reduced and the manufacturing difficulty thereof can be lowered.

Alternatively or additionally, according to some example embodiments, a channel width of a transfer transistor can be increased due to a vertically extended transfer channel region.

Alternatively or additionally, according to some example embodiments, since the channel width of the transfer transistor is increased, it is possible to reduce a noise and a leakage current of the transfer transistor. Therefore, the performance of the image sensor can be improved.

Alternatively or additionally, according to some example embodiments, since a transfer gate of the transfer transistor and a source follower gate of the source follower transistor can be formed using substantially the same manufacturing method, the manufacturing cost of the image sensor can be reduced and the manufacturing difficulty thereof can be lowered.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

The above-described contents are specific example embodiments for implementing inventive concepts. In addition to the above-described example embodiments, inventive concepts will also include example embodiments that may be simply changed in design or easily modified. Alternatively or additionally, inventive concepts will also include technologies that may be easily modified and implemented using some example embodiments. Therefore, the scope of the present disclosure should not be limited to the above-described example embodiments, but should be determined not only by the appended claims but also by the equivalents of the claims of inventive concepts. Additionally example embodiments are not necessarily mutually exclusive with one another. For example, some example embodiments may include one or more features described with reference to one or more figures, and may also include one or more other features described with reference to one or more other figures.

What is claimed is:

1. An image sensor comprising:
a deep element isolation pattern in a substrate and defining pixel region groups, each of the pixel region groups including at least one pixel region;
a shallow element isolation pattern filling a shallow trench recessed from one surface of the substrate and defining a plurality of active regions in each of the pixel region groups;
a source follower gate on a first active region among the plurality of active regions and including a pair of first vertical portions, the pair of first vertical portions respectively filling a pair of first gate recesses in the first active region and spaced laterally apart from each other, with a source follower channel region defined between the pair of first gate recesses;
a first gate insulating film between the source follower gate and the source follower channel region,
wherein
a width of the source follower channel region gradually decreases in a depth direction of the first gate recesses.

2. The image sensor of claim 1, wherein
the source follower channel region is spaced apart from the substrate,
the substrate under the source follower channel region includes a protrusion protruding toward the source follower channel region, and
a width of the protrusion gradually decreases toward the source follower channel region.

3. The image sensor of claim 2, wherein
the pair of first gate recesses and the pair of first vertical portions extend downward and define the protrusion of the substrate, and
the first gate insulating film extends and is between the protrusion of the substrate and the pair of first vertical portions.

4. The image sensor of claim 3, wherein
the first gate insulating film completely fills a space between the source follower gate and the protrusion.

5. The image sensor of claim 3, wherein
the first gate insulating film on a surface of the source follower channel region is spaced apart from the first gate insulating film on a surface of the protrusion, and
the pair of first vertical portions are connected to each other and extend between the source follower channel region and the protrusion.

6. The image sensor of claim 1, wherein
the source follower gate further includes a first horizontal portion connected to upper ends of the pair of first vertical portions,
the first horizontal portion covers an upper surface of the source follower channel region, and
the first gate insulating film extends between the first horizontal portion and the upper surface of the source follower channel region.

7. The image sensor of claim 1, further comprising:
a transfer gate on a second active region among the plurality of active regions and including a pair of second vertical portions, the pair of second vertical portions respectively filling a pair of second gate recesses in the second active region and spaced laterally apart from each other, and a transfer channel region defined between the pair of second gate recesses; and
a second gate insulating film between the transfer gate and the transfer channel region,
wherein
the transfer channel region is connected to the substrate.

8. The image sensor of claim 7, wherein
a maximum width of the transfer channel region is larger than a maximum width of the source follower channel region.

9. The image sensor of claim 8, wherein
the transfer channel region includes a first portion and a second portion sequentially stacked and connected to each other, corresponding to a single body,
a width of the first portion gradually decreases toward the second portion, and
a width of the second portion gradually decreases toward the first portion.

10. The image sensor of claim 9, wherein
the first portion is connected to the substrate.

11. An image sensor comprising:
a deep element isolation pattern in a substrate and defining pixel region groups, each of the pixel region groups including at least one pixel region;
a shallow element isolation pattern filling a shallow trench recessed from one surface of the substrate and defining a plurality of first active regions in each of the pixel region groups;
a source follower gate in each of the plurality of first active regions and including a pair of first vertical portions, the pair of first vertical portions respectively filling a pair of first gate recesses in each of the first active regions and spaced laterally apart from each other, and a source follower channel region defined between the pair of first gate recesses of each of the first active regions; and
a plurality of first gate insulating films between the source follower gate and the source follower channel region,
wherein
a width of each source follower channel region gradually decreases in a depth direction of the first gate recesses.

12. The image sensor of claim 11, wherein
first end portions of the first active regions at one side of the source follower gate extend and are connected to each other, and
second end portions of the first active regions at another side of the source follower gate extend and are connected to each other.

13. The image sensor of claim 11, wherein
the source follower gate further includes a first horizontal portion connected to upper ends of the first vertical portions in the first active regions,
the first horizontal portion covers upper surfaces of each source follower channel region of the first active regions, and
a one of the plurality of first gate insulating films extends and is arranged between the first horizontal portion and the upper surfaces of the each source follower channel region.

14. The image sensor of claim 13, wherein
the first horizontal portion covers the shallow element isolation pattern between the first active regions.

15. The image sensor of claim 11, wherein
the substrate includes a plurality of protrusions respectively defined between the pair of first gate recesses of each of the first active regions and protrudes toward the source follower channel region, and
the plurality of protrusions respectively corresponding to the first active regions are spaced apart from the respective source follower channel region.

16. An image sensor comprising:
a deep element isolation pattern in a substrate and defining pixel region groups, each of the pixel region groups including at least one pixel region;
a shallow element isolation pattern filling a shallow trench recessed from one surface of the substrate and defining a plurality of active regions in each of the pixel region groups;
a source follower gate on a first active region among the plurality of active regions and including a pair of first vertical portions, the pair of first vertical portions respectively filling a pair of first gate recesses that are provided in the first active region and spaced laterally apart from each other, a source follower channel region defined between the pair of gate recesses;
a transfer gate on a second active region among the plurality of active regions and including a pair of second vertical portions, the pair of second vertical portions respectively filling a pair of second gate recesses in the second active region and spaced laterally apart from each other, a transfer channel region defined between the pair of second gate recesses;
a first gate insulating film between the source follower gate and the source follower channel region; and
a second gate insulating film between the transfer gate and the transfer channel region,
wherein
the source follower channel region is spaced apart from the substrate,
the transfer channel region is connected to the substrate,
the substrate under the source follower channel region includes a protrusion protruding toward the source follower channel region, and
a maximum width of the transfer channel region is larger than a maximum width of the source follower channel region.

17. The image sensor of claim 16, wherein
a minimum width of the transfer channel region is larger than a minimum width of the source follower channel region.

18. The image sensor of claim 16, wherein
a width of the source follower channel region gradually decreases toward the protrusion, and
a width of the transfer channel region gradually decreases and then gradually increases in a depth direction of the second gate recesses.

19. The image sensor of claim 16, wherein
a depth of the first gate recesses and a depth of the second gate recesses are same.

20. The image sensor of claim 16, wherein
the source follower gate further includes a first horizontal portion connected to upper ends of the pair of first vertical portions,
the transfer gate further includes a second horizontal portion connected to upper ends of the pair of second vertical portions,
the first horizontal portion covers an upper surface of the source follower channel region, and the second horizontal portion covers an upper surface of the transfer channel region,
the first gate insulating film extends and is arranged between the first horizontal portion and the upper surface of the source follower channel region, and
the second gate insulating film extends and is arranged between the second horizontal portion and the upper surface of the transfer channel region.
